(19) United States
(12) Patent Application Publication
(10) Pub. No.: US 2023/0200251 A1
(43) Pub. Date: Jun. 22, 2023

(54) CONTROL METHOD FOR PIEZOELECTRIC MOTOR, PIEZOELECTRIC MOTOR, AND ROBOT

(71) Applicant: SEIKO EPSON CORPORATION, Tokyo (JP)

(72) Inventor: Tomoaki TAKAHASHI, MATSUMOTO-SHI (JP)

(21) Appl. No.: 18/080,762

(22) Filed: Dec. 14, 2022

(30) Foreign Application Priority Data
Dec. 16, 2021 (JP) 2021-204005

(51) Int. Cl. H10N 30/80; H02N 2/06; H10N 30/20

(52) U.S. Cl. CPC H10N 30/802; H02N 2/06; H10N 30/2041

(57) ABSTRACT

A control method for a piezoelectric motor having a vibrating portion including a piezoelectric element and a transmitting portion transmitting vibration of the vibrating portion to a driven member, and synthesizing longitudinal vibration and flexural vibration by energization of the piezoelectric element to vibrate the vibrating portion and elliptically move the transmitting portion and moving the driven member by the elliptical motion, includes changing an orbit of the elliptical motion according to a load received by the transmitting portion.

The present application is based on, and claims priority from JP Application Serial Number 2021-204005, filed Dec. 16, 2021, the disclosure of which is hereby incorporated by reference herein in its entirety.

### BACKGROUND

### 1. Technical Field

The present disclosure relates to a control method for a piezoelectric motor, a piezoelectric motor, and a robot.

### 2. Related Art

For example, in a piezoelectric motor disclosed in JP-A-2021-027621, a piezoelectric vibrator excites elliptical vibration as superimposition of thrust-up vibration in a pressurization direction and flexural vibration in a direction perpendicular to the pressurization direction, and a driven member is driven by the elliptical vibration. Further, in the piezoelectric motor, an amplitude ratio of the flexural vibration to the thrust-up vibration is changed, and thereby, the speed of the driven member is changed.

However, in the piezoelectric motor, it is difficult to reduce wear of a contact portion of the piezoelectric motor with the driven member and a contact portion of the driven member with the piezoelectric motor and extend the life of the piezoelectric motor.

### SUMMARY

A control method for a piezoelectric motor according to an aspect of the present disclosure is a control method for a piezoelectric motor having a vibrating portion including a piezoelectric element and a transmitting portion transmitting vibration of the vibrating portion to a driven member, and synthesizing longitudinal vibration and flexural vibration by energization of the piezoelectric element to vibrate the vibrating portion and elliptically move the transmitting portion and moving the driven member by the elliptical motion, including changing an orbit of the elliptical motion according to a load received by the transmitting portion.

A piezoelectric motor according to an aspect of the present disclosure includes a driven member, a piezoelectric actuator having a vibrating portion including a piezoelectric element and a transmitting portion transmitting vibration of the vibrating portion to the driven member and synthesizing longitudinal vibration and flexural vibration by energization of the piezoelectric element to vibrate the vibrating portion and elliptically move the transmitting portion and moving the driven member by the elliptical motion, and a controller controlling driving of the piezoelectric actuator, wherein the controller changes an orbit of the elliptical motion according to a load received by the transmitting portion.

A robot according to an aspect of the present disclosure includes a piezoelectric motor, and a movable unit driven by driving of the piezoelectric motor, wherein the piezoelectric motor has a driven member, a piezoelectric actuator having a vibrating portion including a piezoelectric element and a transmitting portion transmitting vibration of the vibrating portion to the driven member and synthesizing longitudinal vibration and flexural vibration by energization of the piezoelectric element to vibrate the vibrating portion and elliptically move the transmitting portion and moving the driven member by the elliptical motion, and a controller controlling driving of the piezoelectric actuator, and the controller changes an orbit of the elliptical motion according to a load received by the transmitting portion.

### BRIEF DESCRIPTION OF THE DRAWINGS

FIG. 1 is, a plan view showing a piezoelectric motor according to a first embodiment.

FIG. 2 shows drive signals applied to a piezoelectric actuator.

FIG. 3 is a plan view showing a driving state of the piezoelectric actuator when the drive signals in FIG. 2 are applied.

FIG. 4 shows drive signals applied to the piezoelectric actuator.

FIG. 5 is a plan view showing a driving state of the piezoelectric actuator when the drive signals in FIG. 4 are applied.

FIG. 6 is a plan view showing a state of the piezoelectric actuator when a load is applied.

FIG. 7 is a plan view showing a state of the piezoelectric actuator when a load is applied.

FIG. 8 is a graph when a phase difference θ in amplitude between longitudinal vibration and flexural vibration is 15°.

FIG. 9 is a graph showing an orbit of elliptical motion when the phase difference θ in amplitude between longitudinal vibration and flexural vibration is 15°.

FIG. 10 is a graph when the phase difference θ in amplitude between longitudinal vibration and flexural vibration is 90°.

FIG. 11 is a graph showing an orbit of elliptical motion when the phase difference θ in amplitude between longitudinal vibration and flexural vibration is 90°.

FIG. 12 is a graph showing changes of the orbit of elliptical motion depending on frequencies of the drive signal.

FIG. 13 is a graph showing relationships between a phase difference θv when the load is zero and a rotor speed and an amount of heat generation.

FIG. 14 is a graph showing relationships between the phase difference θv when the load is 25% of a retaining force and the rotor speed and the amount of heat generation.

FIG. 15 is a graph showing relationships between the phase difference ƒv when the load is 50% of the retaining force and the rotor speed and the amount of heat generation.

FIG. 16 is a flowchart showing a control method for the piezoelectric motor.

FIG. 17 is a graph showing a relationship between the load and the phase difference.

FIG. 18 is a perspective view showing a robot according to a second embodiment.

### DESCRIPTION OF EXEMPLARY EMBODIMENTS

As below, a control method for a piezoelectric motor, a piezoelectric motor, and a robot according to the present disclosure will be explained in detail based on preferred embodiments shown in the accompanying drawings.

### First Embodiment

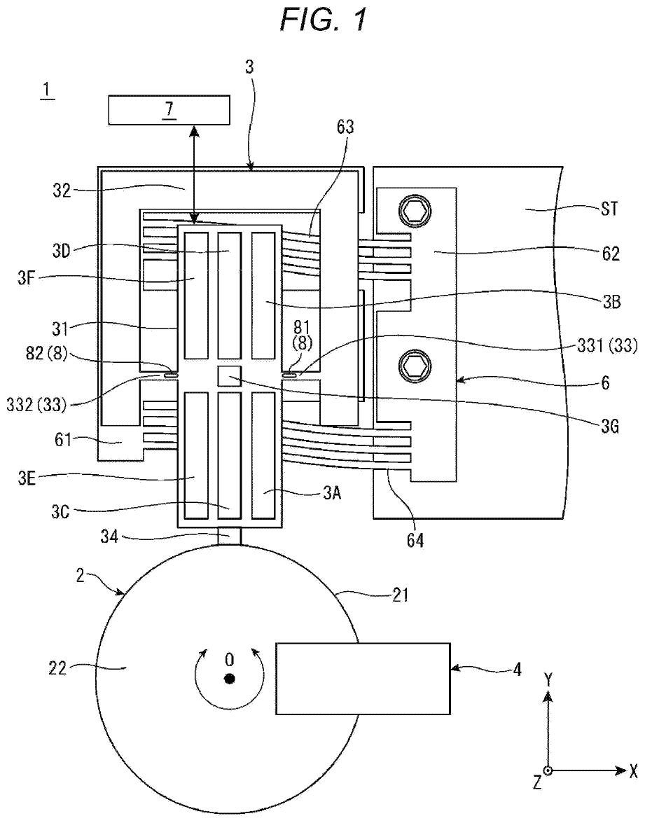

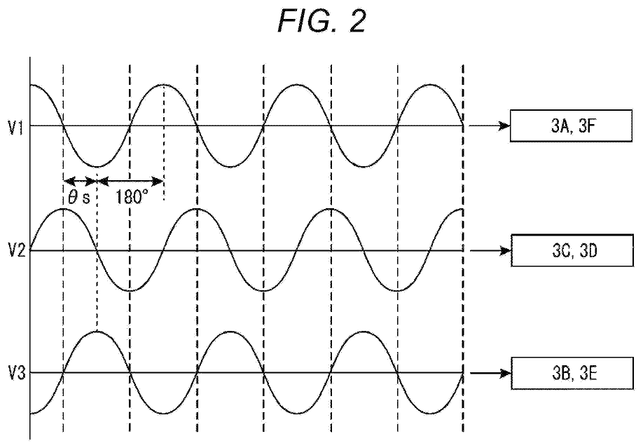

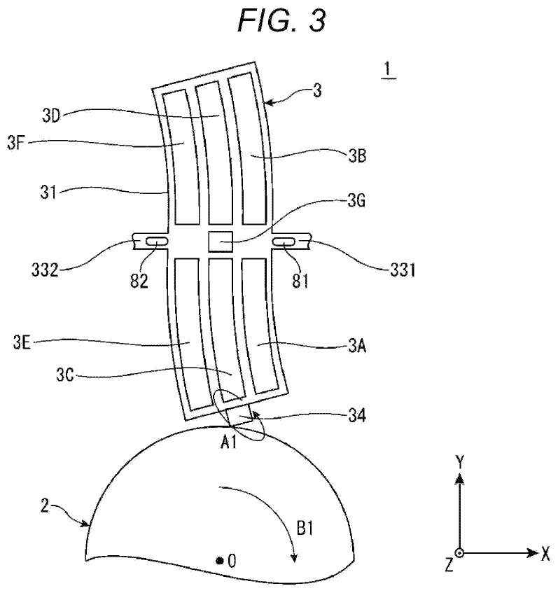

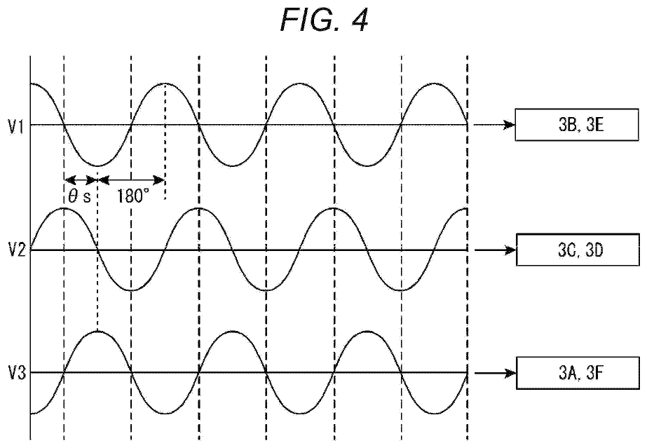

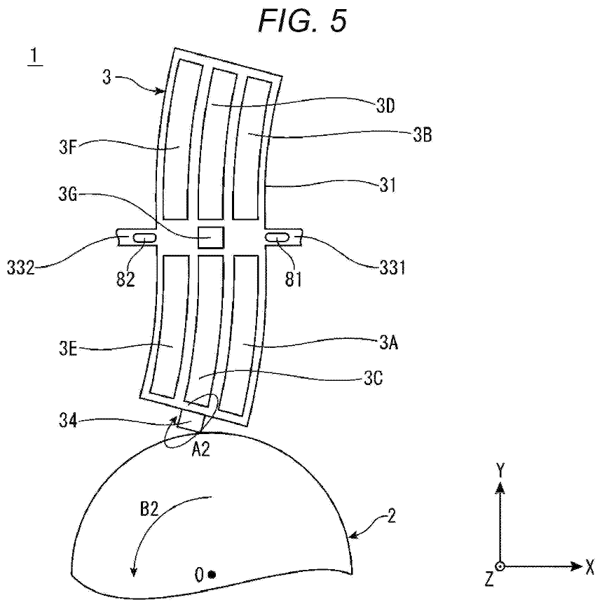

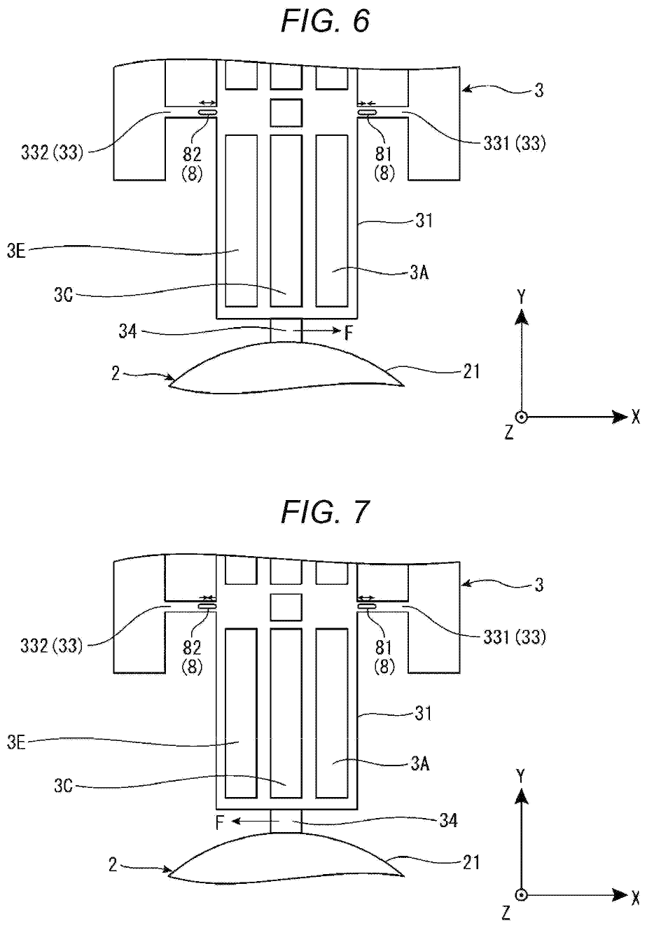

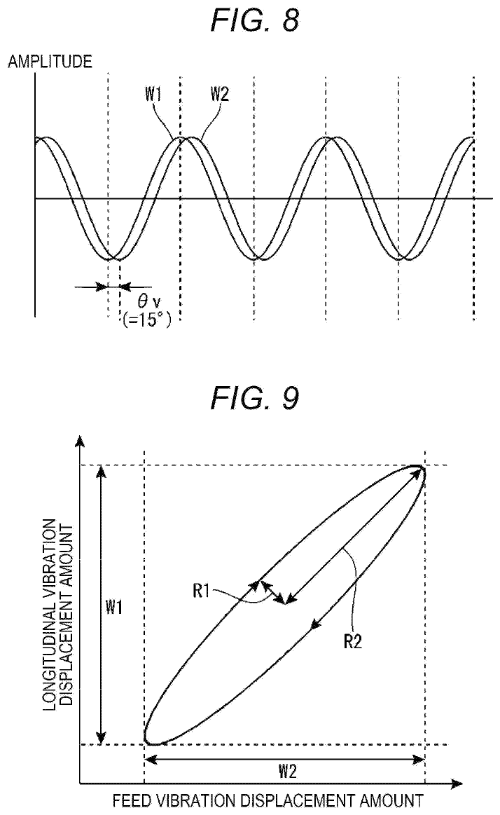

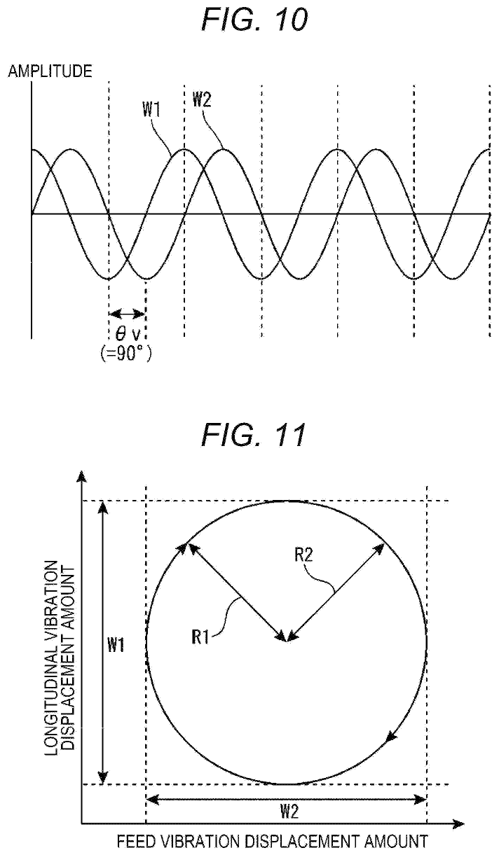

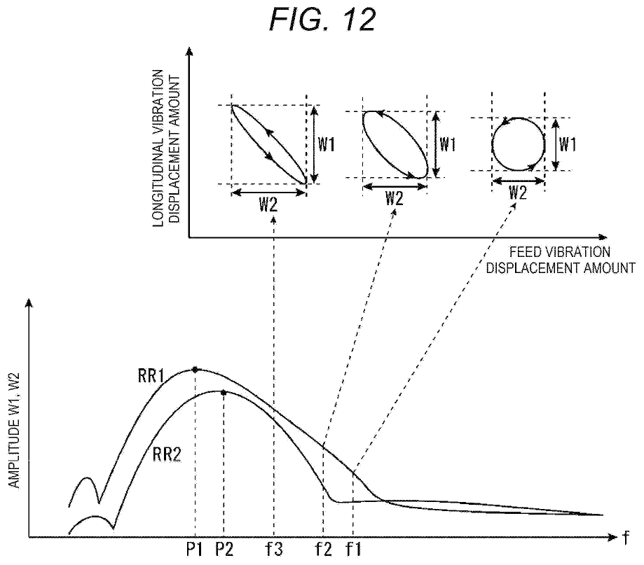

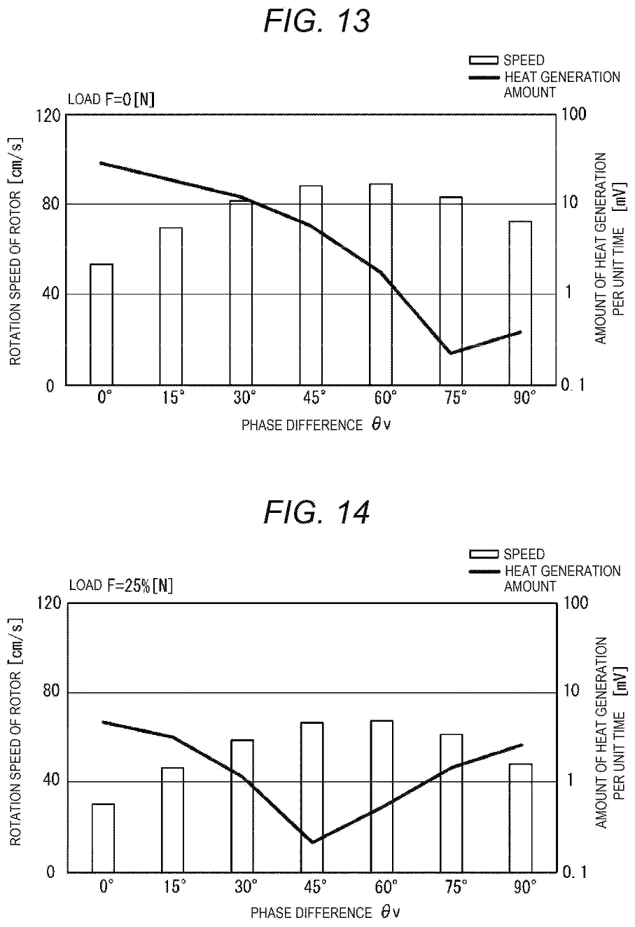

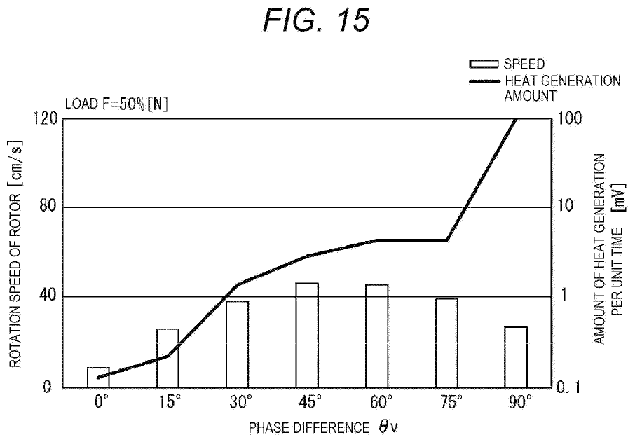

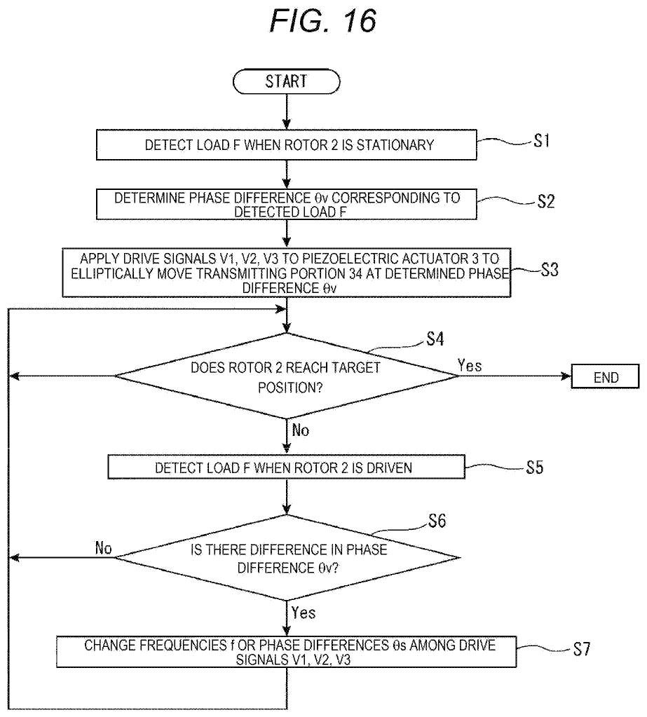

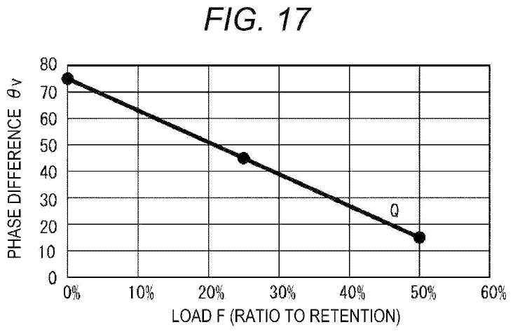

FIG. 1 is a plan view showing a piezoelectric motor according to a first embodiment. FIG. 2 shows drive signals applied to a piezoelectric actuator. FIG. 3 is a plan view showing a driving state of the piezoelectric actuator when the drive signals in FIG. 2 are applied. FIG. 4 shows drive signals applied to the piezoelectric actuator. FIG. 5 is a plan view showing a driving state of the piezoelectric actuator when the drive signals in FIG. 4 are applied. FIGS. 6 and 7 are plan views showing states of the piezoelectric actuator when loads are applied. FIG. 8 is a graph when a phase difference θ in amplitude between longitudinal vibration and flexural vibration is 15°. FIG. 9 is a graph showing an orbit of elliptical motion when the phase difference θ in amplitude between longitudinal vibration and flexural vibration is 15°. FIG. 10 is a graph when the phase difference θ in amplitude between longitudinal vibration and flexural vibration is 90°. FIG. 11 is a graph showing an orbit of elliptical motion when the phase difference θ in amplitude between longitudinal vibration and flexural vibration is 90°. FIG. 12 is a graph showing changes of the orbit of elliptical motion depending on frequencies of the drive signal. FIG. 13 is a graph showing relationships between a phase difference θv when the load is zero and a rotor speed and an amount of heat generation. FIG. 14 is a graph showing relationships between the phase difference θv when the load is 25% of a retaining force and the rotor speed and the amount of heat generation. FIG. 15 is a graph showing relationships between the phase difference θv when the load is 50% of the retaining force and the rotor speed and the amount of heat generation. FIG. 16 is a flowchart showing a control method for the piezoelectric motor. FIG. 17 is a graph showing a relationship between the load and the phase difference.

Hereinafter, for convenience of explanation, the rotor side of the piezoelectric actuator is also referred to as “distal end side” and the opposite side to the rotor is also referred to as “proximal end side”. Further, three axes orthogonal to one another are referred to as “X-axis”, “Y-axis”, and “Z-axis”, directions along the X-axis are also referred to as “X-axis directions”, directions along the Y-axis are also referred to as “Y-axis directions”, and directions along the Z-axis are also referred to as “Z-axis directions”. Furthermore, arrow head sides of the respective axes are also referred to as “plus sides” and the opposite sides to the head sides are also referred to as “minus sides”.

As shown in FIG. 1, a piezoelectric motor 1 has a rotor 2 as a driven member rotatable around a rotation axis O, an encoder 4 detecting an amount of rotation of the rotor 2, a piezoelectric actuator 3 in contact with an outer circumferential surface 21 of the rotor 2, an urging member 6 pressing the piezoelectric actuator 3 against the rotor 2, a controller 7 controlling driving of the piezoelectric actuator 3, and a load detection unit 8 detecting a load F applied to the piezoelectric actuator 3. In the piezoelectric motor 1, the piezoelectric actuator 3 drives under control by the controller 7, a drive force generated in the piezoelectric actuator 3 is transmitted to the rotor 2, and the rotor 2 rotates around the rotation axis O.

Note that the configuration of the piezoelectric motor 1 is not particularly limited. For example, a plurality of the piezoelectric actuators 3 may be placed along the circumferential direction of the rotor 2 and the rotor 2 may be rotated by driving of the plurality of the piezoelectric actuators 3. Further, the piezoelectric actuator 3 may be in contact with a principal surface 22 of the rotor 2 instead of the outer circumferential surface 21 of the rotor 2. Furthermore, the driven member is not limited to a rotor such as the rotor 2, but may be e.g. a slider that linearly moves.

The piezoelectric actuator 3 further has a vibrating portion 31, a supporting portion 32 supporting the vibrating portion 31, beam portion 33 coupling the vibrating portion 31 and the supporting portion 32, and a convex transmitting portion 34 fixed to the distal end part of the vibrating portion 31 and transmitting the vibration of the vibrating portion 31 to the rotor 2.

The vibrating portion 31 is in a plate shape having a thickness in the Z-axis directions and spreading in an XY-plane containing the X-axis and the Y-axis. Further, the vibrating portion 31 has an elongated shape longitudinal in the Y-axis directions as expansion and contract directions, particularly, a rectangular shape in the embodiment in a plan view. Note that the shape of the vibrating portion 31 is not particularly limited as long as the portion may fulfill the function.

The vibrating portion 31 has piezoelectric elements 3A, 3B, 3C, 3D, 3E, 3F for driving that flexurally vibrates the vibrating portion 31 and a piezoelectric element 3G for detection that detects the vibration state of the vibrating portion 31. The piezoelectric elements 3C, 3D are adjacently placed in the Y-axis directions in the center part of the vibrating portion 31. Further, the piezoelectric elements 3A, 3B are adjacently placed in the Y-axis directions at the plus side in the X-axis direction of the piezoelectric elements 3C, 3D, and the piezoelectric elements 3E, 3F are adjacently placed in the Y-axis directions at the minus side in the X-axis direction.

These piezoelectric elements 3A to 3F respectively expand and contract in the Y-axis directions by energization. Of the elements, the piezoelectric elements 3C, 3D are piezoelectric elements for longitudinal vibration for exciting longitudinal vibration of expansion and contraction in the Y-axis directions of the vibrating portion 31, and the piezoelectric elements 3A, 3B, 3E, 3F are piezoelectric elements for flexural vibration for exciting flexural vibration (feed vibration) of flexion in S-shapes in the X-axis directions of the vibrating portion 31.

The piezoelectric element 3G is placed between the piezoelectric elements 3C, 3D. The piezoelectric element 3G deforms according to the longitudinal vibration of the vibrating portion 31 and outputs a detection signal according to the longitudinal vibration. Note that the number and placement of the piezoelectric elements for driving are not particularly limited as long as the elements may excite predetermined vibration of the vibrating portion 31. Further, the piezoelectric element 3G for detection may be omitted.

The transmitting portion 34 is provided in the distal end part, i.e., an end part at the minus side in the Y-axis direction of the vibrating portion 31 and projects from the vibrating portion 31 toward the rotor 2. The distal end part of the transmitting portion 34 contacts the outer circumferential surface 21 of the rotor 2 and is pressed by the urging member 6. Accordingly, the vibration of the vibrating portion 31 is transmitted to the rotor 2 via the transmitting portion 34.

The supporting portion 32 supports the vibrating portion 31. The supporting portion 32 has a U-shape surrounding both sides and the proximal end side of the vibrating portion 31 in the plan view. Note that the configuration of the supporting portion 32 is not particularly limited as long as the portion may fulfill the function.

The beam portion 33 couples parts as nodes of the flexural vibration of the vibrating portion 31, specifically, the center part in the Y-axis directions and the supporting portion 32. The beam portion 33 has a first beam portion 331 located at the plus side in the X-axis direction of the vibrating portion 31 and coupling the vibrating portion 31 and the supporting portion 32 and a second beam portion 332 located at the minus side in the X-axis direction of the vibrating portion 31 and coupling the vibrating portion 31 and the supporting portion 32.

The urging member 6 urges the piezoelectric actuator 3 toward the rotor 2 and presses the transmitting portion 34 against the outer circumferential surface 21 of the rotor 2. The urging member 6 has a holding portion 61 fixed to the supporting portion 32, a base 62 fixed to a stage ST as an object for fixation, and a pair of spring groups 63, 64 coupling the holding portion 61 and the base 62. With the spring groups 63, 64 elastically deformed in the Y-axis directions, the piezoelectric actuator 3 is fixed to the stage ST, and thereby, the piezoelectric actuator 3 is urged toward the minus side in the Y-axis direction and the transmitting portion 34 is pressed against the outer circumferential surface 21 of the rotor 2.

The controller 7 includes e.g. a computer and has a processor processing information, a memory communicably coupled to the processor, and an external interface. A program that can be executed by the processor is stored in the memory and the processor reads and executes the program stored in the memory. The controller 7 receives a command from a host computer (not shown) and drives the piezoelectric actuator 3 based on the command.

For example, when a drive signal V1 shown in FIG. 2 is applied to the piezoelectric elements 3A, 3F as the piezoelectric elements for flexural vibration, a drive signal V2 is applied to the piezoelectric elements 3C, 3D as the piezoelectric elements for longitudinal vibration, and a drive signal V3 is applied to the piezoelectric elements 3B, 3E as the piezoelectric elements for flexural vibration, as shown in FIG. 3, the vibrating portion 31 stretchingly vibrates in the Y-axis directions and flexurally vibrates in an inverted S-shape in the X-axis directions and these vibrations are synthesized, and the distal end of the transmitting portion 34 makes an elliptical motion moving on an elliptical orbit counterclockwise as shown by an arrow A1. Thereby, the rotor 2 is fed and the rotor 2 rotates clockwise as shown by an arrow B1.

On the other hand, when the waveforms of the drive signals V1, V3 are changed, that is, as shown in FIG. 4, when the drive signal V1 is applied to the piezoelectric elements 3B, 3E, the drive signal V2 is applied to the piezoelectric elements 3C, 3D, and the drive signal V3 is applied to the piezoelectric elements 3A, 3F, as shown in FIG. 5, the vibrating portion 31 stretchingly vibrates in the Y-axis directions and flexurally vibrates in an S-shape in the X-axis directions and these vibrations are synthesized, and the transmitting portion 34 makes an elliptical motion moving on an elliptical orbit clockwise as shown by an arrow A2. Thereby, the rotor 2 is fed and the rotor 2 rotates counterclockwise as shown by an arrow B2.

Note that “elliptical motion” is not limited to a motion in a motion orbit of the transmitting portion 34 coincident with an ellipse, but includes e.g. various circular motions in circular, oval, or other orbits shifted from the elliptical orbit.

When the above described drive signals V1, V2, V3 are not applied and driving of the piezoelectric actuator 3 is stopped, the state in which the transmitting portion 34 is pressed against the rotor 2 by the urging member 6 is maintained. Accordingly, the rotor 2 is braked by friction resistance to the transmitting portion 34, and the rotor 2 does not rotate.

As shown in FIG. 1, the load detection unit 8 has a first load detection piezoelectric element 81 placed in the first beam portion 331 and a second load detection piezoelectric element 82 placed in the second beam portion 332. For example, when the load F is not applied, the first load detection piezoelectric element 81 and the second load detection piezoelectric element 82 symmetrically bend and detection signals output from these elements are substantially the same as each other.

On the other hand, as shown in FIG. 6, when the load F toward the plus side in the X-axis direction is applied to the transmitting portion 34, the transmitting portion 34 is pulled toward the plus side in the X-axis direction by the load F, and compression stress is applied to the first load detection piezoelectric element 81 and tensile stress is applied to the second load detection piezoelectric element 82. Accordingly, a difference is produced between the detection signals output from the first load detection piezoelectric element 81 and the second load detection piezoelectric element 82.

Contrary, as shown in FIG. 7, when the load F toward the minus side in the X-axis direction is applied, the transmitting portion 34 is pulled toward the minus side in the X-axis direction by the load F, and tensile stress is applied to the first load detection piezoelectric element 81 and compression stress is applied to the second load detection piezoelectric element 82. Accordingly, an opposite difference to that when the load F toward the plus side in the X-axis direction is applied is produced between the detection signals output from the first load detection piezoelectric element 81 and the second load detection piezoelectric element 82.

Therefore, whether or not the load F is applied and the direction in which the load F is applied may be easily and accurately detected based on the difference between the detection signals output from the first load detection piezoelectric element 81 and the second load detection piezoelectric element 82. Further, the magnitude of the load F may be detected from the magnitude of the difference. Note that the configuration of the load detection unit 8 is not particularly limited. For example, both the first, second load detection piezoelectric elements 81, 82 may be adjacently placed in one of the first, second beam portions 331, 332.

As above, the configuration of the piezoelectric motor 1 is briefly explained. Next, a control method for the piezoelectric motor 1 by the controller 7 will be explained. The controller 7 changes the orbit of the elliptical motion of the transmitting portion 34 according to the direction and the magnitude of the load F received by the transmitting portion 34. According to the control method, frictional sliding (slip) of the transmitting portion 34 and the rotor 2 is reduced and frictional wear of the transmitting portion 34 and the rotor 2 may be reduced. Accordingly, the life of the piezoelectric motor 1 may be extended. That is, excellent reliability may be stably exerted for a long period. As below, in the specific description, for convenience of explanation, as shown in FIGS. 2 and 3, the case where the rotor 2 is rotated in the arrow B1 direction will be explained. Hereinafter, amplitude of longitudinal vibration as a component forming an elliptical motion is W1, amplitude of flexural vibration is W2, and R1/R2 as a ratio of a short axis radius R1 to a long axis radius R2 of the elliptical motion is an elliptical ratio.

The controller 7 sets the elliptical ratio R1/R2 to be smaller as the load F toward the minus side in the X-axis direction is larger. That is, the controller sets the orbit of the elliptical motion to be thinner. Thereby, the frictional sliding of the transmitting portion 34 and the rotor 2 is reduced, and the frictional wear of the transmitting portion 34 and the rotor 2 may be reduced. The effect will be proved based on experimental results shown in FIGS. 13 to 15. Before that, a method of changing the orbit of the elliptical motion is explained.

The controller 7 changes the orbit of the elliptical motion by changing the phase difference By between the longitudinal vibration and the flexural vibration. Specifically, the orbit of the elliptical motion changes from the thin elliptical shape close to a circular shape as the phase difference θv is increased from 0° to 90°. For example, when the phase difference θv=15°, the orbit of the elliptical motion has the thin elliptical shape as shown in FIGS. 8 and 9 and, when the phase difference θv=90°, the orbit of the elliptical motion has substantially the circular shape as shown in FIGS. 10 and 11. According to the method of changing the phase difference θv, the orbit of the elliptical motion may be easily and accurately changed. Particularly, according to the method, the amplitude W, W2 is kept substantially constant even when the phase difference θv is changed. Therefore, the amount of feeding of the rotor 2 is maintained and driving of the rotor 2 becomes more stable.

The method of changing the phase difference θv is not particularly limited to, but includes a method of changing a phase difference θs (see FIGS. 2 and 4) between the drive signal V2 for longitudinal vibration and the drive signal V1 for flexural vibration with the phase difference between the drive signals V1, V3 kept at 180°. According to the method, the phase difference By may be easily and accurately changed.

Alternatively, as shown in FIG. 12, another method of changing frequencies f of the drive signals V1, V2, VS may be employed. In the example of FIG. 12, frequency-vibration characteristics RR1, RR2 of the longitudinal vibration and the flexural vibration are set to be different, and the phase difference By may be changed using the difference. For example, when the frequency f=f1, the orbit of the elliptical motion is substantially a circular shape. Further, as shown by frequencies f2, f3, the orbit of the elliptical motion is gradually thinner as the frequency f is set to be closer to resonance peaks P1, P2 from the frequency f1. Also, according to the method, the phase difference θv between the longitudinal vibration and the flexural vibration may be easily and accurately changed.

As above, the method of changing the orbit of the elliptical motion is briefly described. Next, reduction of the frictional wear of the transmitting portion 34 and the rotor 2 by setting of the elliptical ratio R1/R2 to be smaller as the load F at the minus side in the X-axis direction is larger will be proved based on the experimental results shown in FIGS. 13 to 15.

FIG. 13 is the graph showing the relationships between the phase difference θv when the load F at the minus side in the X-axis direction is zero and a rotation speed and an amount of heat generation per unit time of the rotor 2. Note that, as the friction sliding of the transmitting portion 34 and the rotor 2 is larger, the amount of heat generation is larger, and the frictional wear of the transmitting portion 34 and the rotor 2 is heavier as the amount of heat generation is larger. Accordingly, here, the amount of heat generation is used as the degree of frictional wear. As known from the graph, when the load F is zero, the amount of heat generation is the minimum for θv=75°. Therefore, the transmitting portion 34 makes the elliptical motion at θv=75°, and thereby, the frictional wear of the transmitting portion 34 and the rotor 2 may be effectively reduced.

FIG. 14 is the graph showing relationships between the phase difference θv when the load F at the minus side in the X-axis direction is 25% of the retaining force and the rotation speed and the amount of heat generation per unit time of the rotor 2. Note that the retaining force refers to a force for retaining the stationary state of the rotor 2, when the load F equal to or less than the retaining force is applied to the stationary rotor 2, the stationary state may be kept and, when the load F more than the retaining force is applied, the rotor 2 unintentionally rotates irresistibly to the load F. As known from the graph, when the load F is 25% of the retaining force, the amount of heat generation is the minimum for θv=45°. Therefore, the transmitting portion 34 makes the elliptical motion at θv=45°, and thereby, the frictional wear of the transmitting portion 34 and the rotor 2 may be effectively reduced.

FIG. 15 is the graph showing relationships between the phase difference By when the load F at the minus side in the X-axis direction is 50% of the retaining force and the rotation speed and the amount of heat generation per unit time of the rotor 2. As known from the graph, when the load F is 50% of the retaining force, the amount of heat generation is the minimum for θv=0°. Therefore, the transmitting portion 34 makes the elliptical motion at θv=0°, and thereby, the'frictional wear of the transmitting portion 34 and the rotor 2 may be effectively reduced.

As described above, from the three experimental results, it is proved that the amount of frictional wear of the transmitting portion 34 and the rotor 2 is reduced by setting of the elliptical ratio R1/R2 to be smaller as the load F at the minus side in the X-axis direction is larger.

Next, the control method for the piezoelectric motor 1 will be explained with reference to the flowchart in FIG. 16. First, as step S1, the load F applied to the transmitting portion 34 when the rotor 2 is stationary is detected. Then, as step S2, the phase difference θv corresponding to the detected load F is determined. For example, a relational expression Q between the load F and the phase difference θv shown in FIG. 17 is created from the experimental results in FIGS. 13 to 15, and the phase difference θv may be determined according to the relational expression Q. Note that the method of determining the phase difference By is not particularly limited. For example, the load F may be classified in a plurality of classes of large/middle/small or the like and the phase difference By may be determined with respect to each class.

Then, as step S3, the drive signals V1, V2, V3 are applied to the piezoelectric actuator 3 so that the transmitting portion 34 may make the elliptical motion at the determined phase difference By. Thereby, the rotor 2 rotates.

Then, as step S4, whether or not the rotor 2 reaches a target position is determined based on the output of the encoder 4. When the rotor 2 reaches the target position, the application of the drive signals V1, V2, V3 to the piezoelectric actuator 3 is stopped and driving of the piezoelectric motor 1 is ended. On the other hand, when the rotor 2 does not reach the target position, as step S5, the load F applied to the transmitting portion 34 is detected.

Then, as step S6, whether or not there is a difference between the phase difference θv corresponding to the load F detected at step S5 and the phase difference θv currently set is determined. When there is no difference, returning to step S4, the above described steps are repeated. On the other hand, when there is a difference, as step S7, the frequencies f or the phase differences θs among the drive signals V1, V2, V3 are changed so that the transmitting portion 34 may make the elliptical motion at the phase difference By corresponding to the load F detected at step S5. Then, returning to step S4, the above described steps are repeated.

According to the control method, the load F changing every second may be fed back, and the elliptical motion in the optimal shape may be made at each time. Accordingly, the frictional wear of the transmitting portion 34 and the rotor 2 may be reduced more effectively. Note that the control method is not particularly limited, but, for example, after the phase difference θv is determined at step S2, the phase difference θv may be kept constant until the rotor 2 reaches the target position.

As above, the control method for the piezoelectric motor 1 and the piezoelectric motor 1 of the embodiment are explained. The control method for the piezoelectric motor 1 is the control method for the piezoelectric motor having the vibrating portion 31 including the piezoelectric elements 3A to 3F and the transmitting portion 34 transmitting the vibration of the vibrating portion 31 to the rotor 2 as the driven member, and synthesizing the longitudinal vibration and the flexural vibration by energization of the piezoelectric elements 3A to 3F to vibrate the vibrating portion 31 and elliptically move the transmitting portion 34 and moving the rotor 2 by the elliptical motion, including changing the orbit of the elliptical motion according to the load F received by the transmitting portion 34. As described above, the orbit of the elliptical motion is changed according to the load F received by the transmitting portion 34, and thereby, the frictional sliding of the transmitting portion 34 and the rotor 2 is reduced and the frictional wear of the transmitting portion 34 and the rotor 2 may be reduced. Accordingly, the life of the piezoelectric motor 1 may be extended. That is, excellent reliability may be stably exerted for a long period.

As described above, the piezoelectric motor 1 has the load detection unit 8 detecting the load F and changes the orbit of the elliptical motion based on the detection result of the load detection unit 8. Thereby, the orbit of the elliptical motion may be accurately changed. Further, the load F may be fed back, and the elliptical motion in the optimal shape may be made at each time. Accordingly, the frictional wear of the transmitting portion 34 and the rotor 2 may be reduced more effectively.

As described above, the load detection unit 8 has the first, second load detection piezoelectric elements 81, 82 placed in the beam portion 33 coupled to the vibrating portion 31, and detects the load F based on the output of the first, second load detection piezoelectric elements 81, 82. Thereby, the load F may be accurately detected by the simple configuration.

As described above, in the control method of the piezoelectric motor 1, when the ratio of the short axis radius R1 to the long axis radius R2 of the elliptical motion is the elliptical ratio R1/R2, the elliptical ratio R1/R2 is set to be smaller as the load F is larger. Thereby, the frictional sliding of the transmitting portion 34 and the rotor 2 is reduced and the frictional wear of the transmitting portion 34 and the rotor 2 may be reduced.

As described above, in the control method of the piezoelectric motor 1, the orbit of the elliptical motion is changed by changing of the phase difference θv between the longitudinal vibration and the flexural vibration. According to the method, the orbit of the elliptical motion may be easily and accurately changed. Particularly, according to the method, the amplitude W1, W2 is kept substantially constant even when the phase difference θv is changed. Therefore, the amount of feeding of the rotor 2 is maintained and driving of the rotor 2 becomes more stable.

As described above, in the control method of the piezoelectric motor 1, the piezoelectric elements have the piezoelectric elements 3C, 3D for longitudinal vibration and the piezoelectric elements 3A, 3F for flexural vibration and the phase difference θs between the drive signal V1 as a first drive signal applied to the piezoelectric elements 3A, 3F and the drive signal V2 as a second drive signal applied to the piezoelectric elements 3C, 3D is changed, and thereby, the phase difference θv between the longitudinal vibration and the flexural vibration is changed. According to the method, the phase difference θv may be easily and accurately changed.

As described above, in the control method of the piezoelectric motor 1, the piezoelectric elements have the piezoelectric elements 3C, 3D for longitudinal vibration and the piezoelectric elements 3A, 3B for flexural vibration and the frequencies f of the drive signal V1 as the first drive signal applied to the piezoelectric elements 3C, 3D and the drive signal V2 as the second drive signal applied to the piezoelectric elements 3C, 3D are changed, and thereby, the phase difference θv between the longitudinal vibration and the flexural vibration is changed. According to the method, the phase difference θv may be easily and accurately changed.

As described above, the piezoelectric motor 1 has the rotor 2 as the driven member, the piezoelectric actuator 3 having the vibrating portion 31 including the piezoelectric elements 3A to 3F and the transmitting portion 34 transmitting the vibration of the vibrating portion 31 to the rotor 2 and synthesizing the longitudinal vibration and the flexural vibration by energization of the piezoelectric elements 3A to 3F to vibrate the vibrating portion 31 and elliptically move the transmitting portion 34 and moving the rotor 2 by the elliptical motion, and the controller 7 controlling driving of the piezoelectric actuator 3. Further, the controller 7 changes the orbit of the elliptical motion according to the load F received by the transmitting portion 34. As described above, the orbit of the elliptical motion is changed according to the load F received by the transmitting portion 34, and thereby, the frictional sliding of the transmitting portion 34 and the rotor 2 is reduced and the frictional wear of the transmitting portion 34 and the rotor 2 may be reduced. Accordingly, the life of the piezoelectric motor 1 may be extended. That is, excellent reliability may be stably exerted for a long period.

### Second Embodiment

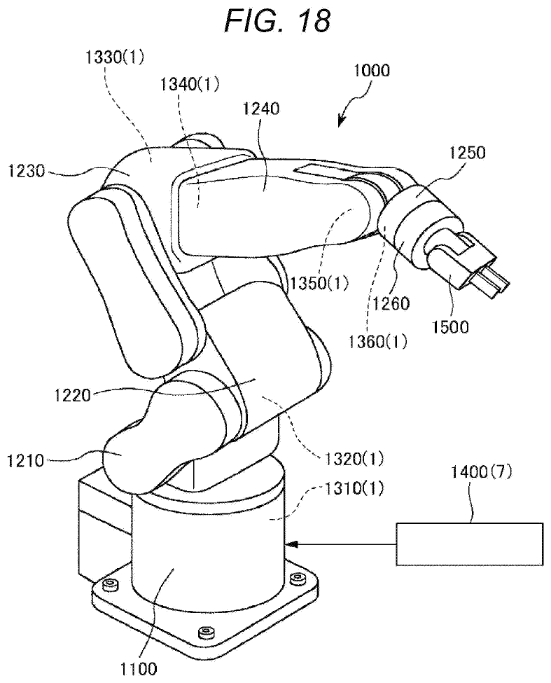

FIG. 18 is a perspective view showing a robot according to a second embodiment.

A robot 1000 shown in FIG. 18 may perform work of feeding, removing, transport, assembly and the like of precision apparatuses and components forming the apparatuses. The robot 1000 is a six-axis robot and has a base 1100 fixed to a floor or a ceiling, a first arm 1210 pivotably coupled to the base 1100, a second arm 1220 pivotably coupled to the first arm 1210, a third arm 1230 pivotably coupled to the second arm 1220, a fourth arm 1240 pivotably coupled to the third arm 1230, a fifth arm 1250 pivotably coupled to the fourth arm 1240, and a sixth arm 1260 pivotably coupled to the fifth arm 1250. Further, a hand coupling portion is provided in the sixth arm 1260 and an end effector 1500 according to work executed by the robot 1000 is attached to the hand coupling portion.

The robot 1000 further has a first arm pivot mechanism 1310 placed in a joint portion between the base 1100 and the first arm 1210 and pivoting the first arm 1210 relative to the base 1100, a second arm pivot mechanism 1320 placed in a joint portion between the first arm 1210 and the second arm 1220 and pivoting the second arm 1220 relative to the first arm 1210, a third arm pivot mechanism 1330 placed in a joint portion between the second arm 1220 and the third arm 1230 and pivoting the third arm 1230 relative to the second arm 1220, a fourth arm pivot mechanism 1340 placed in a joint portion between the third arm 1230 and the fourth arm 1240 and pivoting the fourth arm 1240 relative to the third arm 1230, a fifth arm pivot mechanism 1350 placed in a joint portion between the fourth arm 1240 and the fifth arm 1250 and pivoting the fifth arm 1250 relative to the fourth arm 1240, and a sixth arm pivot mechanism 1360 placed in a joint portion between the fifth arm 1250 and the sixth arm 1260 and pivoting the sixth arm 1260 relative to the fifth arm 1250. Further, the robot 1000 has a robot control unit 1400 controlling driving of these first to sixth arm pivot mechanisms 1310 to 1360.

The piezoelectric motors 1 are provided in at least part of, in the embodiment, all of the first to sixth arm pivot mechanisms 1310 to 1360 as power sources thereof, and the corresponding arms 1210 to 1260 pivot by driving of the piezoelectric motors 1. Thereby, the lives of the first to sixth arm pivot mechanisms 1310 to 1360 may be extended. The robot control unit 1400 includes the controller 7 driving the respective piezoelectric motors 1. Note that, for example, when the piezoelectric motor 1 is provided in the first arm pivot mechanisms 1310, the first arm 1210 corresponds to a movable unit. The same applies to the other pivot mechanisms 1320 to 1360.

As described above, the robot 1000 of the embodiment has the

IS piezoelectric motor 1 and the movable unit (e.g. the first arm 1210) driven by the driving of the piezoelectric motor 1. Further, the robot has the rotor 2 as the driven member, the piezoelectric actuator 3 having the vibrating portion 31 including the piezoelectric elements 3A to 3F and the transmitting portion 34 transmitting the vibration of the vibrating portion 31 to the rotor 2 and synthesizing the longitudinal vibration and the flexural vibration by energization of the piezoelectric elements 3A to 3F to vibrate the vibrating portion 31 and elliptically move the transmitting portion 34 and moving the rotor 2 by the elliptical motion, and the controller 7 controlling driving of the piezoelectric actuator 3. Further, the controller 7 changes the orbit of the elliptical motion according to the load F received by the transmitting portion 34. As described above, the orbit of the elliptical motion is changed according to the load F received by the transmitting portion 34, and thereby, the frictional sliding of the transmitting portion 34 and the rotor 2 is reduced and the frictional wear of the transmitting portion 34 and the rotor 2 may be reduced. Accordingly, the life of the piezoelectric motor 1 may be extended. That is, excellent reliability may be stably exerted for a long period.

According to the second embodiment, the same effects as those of the above described first embodiment may be exerted.

As above, the control method for the piezoelectric motor, the piezoelectric motor, and the robot according to the present disclosure are explained based on the embodiments, however, the present disclosure is not limited to those. The configurations of the respective parts may be replaced by any configurations having the same functions. Further, any other configuration may be added to the present disclosure. The configuration in which the piezoelectric motor is applied to the robot is explained in the above described embodiment, however, the piezoelectric motor may be applied to other various electronic devices requiring drive forces than the robot e.g. a printer, a projector, or the like.

What is claimed is:

1. A control method for a piezoelectric motor having a vibrating portion including a piezoelectric element and a transmitting portion transmitting vibration of the vibrating portion to a driven member, and synthesizing longitudinal vibration and flexural vibration by energization of the piezoelectric element to vibrate the vibrating portion and elliptically move the transmitting portion and moving the driven member by the elliptical motion, comprising changing an orbit of the elliptical motion according to a load received by the transmitting portion.

2. The control method for a piezoelectric motor according to claim 1, wherein
the piezoelectric motor has a load detection unit detecting the load, and
the orbit of the elliptical motion is changed based on a detection result of the load detection unit.

3. The control method for a piezoelectric motor according to claim 2, wherein
the load detection unit has a load detection piezoelectric element placed in a beam portion coupled to the vibrating portion, and
the load is detected based on output of the load detection piezoelectric element.

4. The control method for a piezoelectric motor according to claim 1, wherein
when a ratio of a short axis radius to a long axis radius of the elliptical motion is an elliptical ratio, the elliptical ratio is set to be smaller as the load is larger.

5. The control method fora piezoelectric motor according to claim 1, wherein
the orbit of the elliptical motion is changed by changing of a phase difference between the longitudinal vibration and the flexural vibration.

6. The control method for a piezoelectric motor according to claim 5, wherein
the piezoelectric element has a longitudinal vibration piezoelectric element for longitudinal vibration and a flexural vibration piezoelectric element for flexural vibration, and
the phase difference between the longitudinal vibration and the flexural vibration is changed by changing of a phase difference between a first drive signal applied to the longitudinal vibration piezoelectric element and a second drive signal applied to the flexural vibration piezoelectric element.

7. The control method for a piezoelectric motor according to claim 5, wherein
the piezoelectric element has a longitudinal vibration piezoelectric element for longitudinal vibration and a flexural vibration piezoelectric element for flexural vibration, and
the phase difference between the longitudinal vibration and the flexural vibration is changed by changing of frequencies of a first drive signal applied to the longitudinal vibration piezoelectric element and a second drive signal applied to the flexural vibration piezoelectric element.

8. A piezoelectric motor comprising:
a driven member;
a piezoelectric actuator having a vibrating portion including a piezoelectric element and a transmitting portion transmitting vibration of the vibrating portion to the driven member and synthesizing longitudinal vibration and flexural vibration by energization of the piezoelectric element to vibrate the vibrating portion and elliptically move the transmitting portion and moving the driven member by the elliptical motion; and
a controller controlling driving of the piezoelectric actuator, wherein
the controller changes an orbit of the elliptical motion according to a load received by the transmitting portion.

9. A robot comprising:
a piezoelectric motor; and
a movable unit driven by driving of the piezoelectric motor, wherein the piezoelectric motor has
a driven member,
a piezoelectric actuator having a vibrating portion including a piezoelectric element and a transmitting portion transmitting vibration of the vibrating portion to the driven member and synthesizing longitudinal vibration and flexural vibration by energization of the piezoelectric element to vibrate the vibrating portion and elliptically move the transmitting portion and moving the driven member by the elliptical motion, and
a controller controlling driving of the piezoelectric actuator, and
the controller changes an orbit of the elliptical motion according to a load received by the transmitting portion.
